(19) United States
(12) Patent Application Publication
(10) Pub. No.: US 2025/0291262 A1
(43) Pub. Date: Sep. 18, 2025

(54) OPTICAL APPARATUS AND CONTROL METHOD OF OPTICAL APPARATUS

(71) Applicant: Lasertec Corporation, Yokohama (JP)

(72) Inventor: Hiroki MIYAI, Yokohama-shi (JP)

(21) Appl. No.: 19/080,524

(22) Filed: Mar. 14, 2025

(30) Foreign Application Priority Data
Mar. 15, 2024 (JP) 2024-040932

(51) Int. Cl. G03F 7/00

(52) U.S. Cl. CPC G03F 7/70808; G03F 7/70033; G03F 7/7085

(57) ABSTRACT

An inspection apparatus according to the present embodiment includes an optical system configured to illuminate an object with critical illumination using plasma as a bright point, detecting means for detecting secondary light from the object illuminated by the critical illumination, and plasma forming means for forming at least a first bright point and a second bright point as the bright point, in which the optical system is configured to: illuminate a first region of the object with first critical illumination by first illuminating light generated from the first bright point, and illuminate a second region of the object with second critical illumination by second illuminating light generated from the second bright point.

### INCORPORATION BY REFERENCE

This application is based upon and claims the benefit of priority from Japanese patent application No. 2024-040932, filed on Mar. 15, 2024, the disclosure of which is incorporated herein in its entirety by reference for all purposes.

### BACKGROUND

The present disclosure relates to an optical apparatus and to a control method of an optical apparatus.

Patent Literature 1 discloses a technique for inspecting EUV masks using plasma bright points as critical illumination.
[Patent Literature 1] Japanese Unexamined Patent Application Publication No. 2021-009274

### SUMMARY

Improved inspection throughput is desired.

The present disclosure has been made in consideration of such a problem, and provides an optical apparatus and a control method of an optical apparatus that enable inspection throughput to be improved.

An optical apparatus according to an aspect of the present embodiment includes an optical system configured to illuminate an object with critical illumination using plasma as a bright point, detecting unit configured to detect secondary light from the object illuminated by the critical illumination, and plasma forming unit configured to form at least a first bright point and a second bright point as the bright point, in which the optical system is configured to illuminate a first region of the object with first critical illumination by first illuminating light generated from the first bright point, and illuminate a second region of the object that differs from the first region of the object with second critical illumination by second illuminating light generated from the second bright point, and the detecting unit includes first detecting unit configured to detect first light including the secondary light from the object illuminated by the first critical illumination, and second detecting unit configured to detect second light including the secondary light from the object illuminated by the second critical illumination.

An optical apparatus according to an aspect of the present embodiment includes an optical system configured to illuminate an object with critical illumination using plasma as a bright point, and detecting unit configured to detect secondary light from the object illuminated by the critical illumination, in which the optical system includes a first elliptical mirror configured to illuminate a first region of the object with first critical illumination by first illuminating light generated from a first light flux of light from the bright point, and a second elliptical mirror configured to illuminate a second region of the object that differs from the first region of the object with second critical illumination by second illuminating light generated from a second light flux of the light from the bright point that differs from the first light flux of the light from the bright point, and the detecting unit includes first detecting unit configured to detect first light including the secondary light from the object illuminated by the first critical illumination, and second detecting unit configured to detect second light including the secondary light from the object illuminated by the second critical illumination.

In the optical apparatuses described above, the optical system may be configured to illuminate the second region of the object with the second critical illumination when illuminating the first region of the object with the first critical illumination.

In the optical apparatuses described above, the optical system may include switching unit configured to switch to a first mode in which the second region is illuminated by the second critical illumination or a second mode in which the first region is illuminated by the second critical illumination.

In the optical apparatuses described above, the first detecting unit and the second detecting unit may be alternately provided in a staggered manner as viewed from an optical axis direction of the first light and the second light.

In the optical apparatuses described above, the optical system may include a first elliptical mirror including one focusing point at a position of the first bright point and another focusing point at a position of the first region, and a second elliptical mirror including one focusing point at a position of the second bright point and another focusing point at a position of the second region.

In the optical apparatuses described above, the first elliptical mirror may include one focusing point at a position of the bright point and another focusing point at a position of the first region, and the second elliptical mirror may include one focusing point at a position of the bright point and another focusing point at a position of the second region.

In the optical apparatuses described above, a diaphragm need not be provided on an optical path of the first illuminating light and the second illuminating light from the bright point to the object.

A control method of an optical apparatus according to an aspect of the present embodiment is a control method of an optical apparatus including an optical system configured to illuminate an object with critical illumination using plasma as a bright point, detecting unit configured to detect secondary light from the object illuminated by the critical illumination, and plasma forming unit configured to form at least a first bright point and a second bright point as the bright points, the control method of the optical apparatus including a bright point forming step of causing the plasma forming unit to form at least the first bright point and the second bright point as the bright point, an illuminating step of causing the optical system to illuminate a first region of the object with first critical illumination by first illuminating light generated from the first bright point and to illuminate a second region of the object that differs from the first region of the object with second critical illumination by second illuminating light generated from the second bright point, and a detecting step of causing first detecting unit in the detecting unit to detect first light including the secondary light from the object illuminated by the first critical illumination and causing second detecting unit in the detecting unit to detect second light including the secondary light from the object illuminated by the second critical illumination.

A control method of an optical apparatus according to an aspect of the present embodiment is a control method of an optical apparatus including an optical system configured to illuminate an object with critical illumination using plasma as a bright point, and detecting unit configured to detect secondary light from the object illuminated by the critical illumination, the control method of the optical apparatus including an illuminating step of causing a first elliptical mirror in the optical system to illuminate a first region of the object with first critical illumination by first illuminating light generated from a first light flux of light from the bright point and causing a second elliptical mirror in the optical system to illuminate a second region of the object that differs from the first region of the object with second critical illumination by second illuminating light generated from a second light flux of the light from the bright point that differs from the first light flux of the light from the bright point, and a detecting step of causing first detecting unit in the detecting unit to detect first light including the secondary light from the object illuminated by the first critical illumination and causing second detecting unit in the detecting unit to detect second light including the secondary light from the object illuminated by the second critical illumination.

In the control methods of the optical apparatus described above, in the illuminating step, the optical system may be caused to illuminate the second region of the object with the second critical illumination when illuminating the first region of the object with the first critical illumination.

The control methods of the optical apparatus described above may further include a switching step of causing switching unit to switch to a first mode in which the second region is illuminated by the second critical illumination or to a second mode in which the first region is illuminated by the second critical illumination.

In the control methods of the optical apparatus described above, the first detecting unit and the second detecting unit may be alternately provided in a staggered manner as viewed from an optical axis direction of the first light and the second light.

In the control methods of the optical apparatus described above, in the illuminating step, the first region may be illuminated by a first elliptical mirror including one focusing point at a position of the first bright point and another focusing point at a position of the first region, and the second region may be illuminated by a second elliptical mirror including one focusing point at a position of the second bright point and another focusing point at a position of the second region.

In the control methods of the optical apparatus described above, in the illuminating step, the first elliptical mirror may include one focusing point at a position of the bright point and another focusing point at a position of the first region, and the second elliptical mirror may include one focusing point at a position of the bright point and another focusing point at a position of the second region.

In the control methods of the optical apparatus described above, in the illuminating step, a diaphragm need not be provided on an optical path of the first illuminating light and the second illuminating light from the bright point to the object.

According to the present disclosure, an optical apparatus and a control method of an optical apparatus that enable inspection throughput to be improved can be provided.

The above and other objects, features and advantages of the present disclosure will become more fully understood from the detailed description given hereinbelow and the accompanying drawings.

### BRIEF DESCRIPTION OF DRAWINGS

FIG. 1 is a configuration diagram illustrating an inspection apparatus according to a first embodiment;

FIG. 2 is a diagram illustrating an arrangement of first detecting means and second detecting means in the inspection apparatus according to the first embodiment;

FIG. 3 is a diagram illustrating an arrangement of the first detecting means and the second detecting means in the inspection apparatus according to the first embodiment;

FIG. 4 is a flowchart illustrating a control method of the inspection apparatus according to the first embodiment;

FIG. 5 is a configuration diagram illustrating an inspection apparatus according to a first modified example of the first embodiment;

FIG. 6 is a configuration diagram illustrating an inspection apparatus according to a second modified example of the first embodiment;

FIG. 7 is a flowchart illustrating a control method of the inspection apparatus according to the second modified example of the first embodiment;

FIG. 8 is a configuration diagram illustrating an inspection apparatus according to a second embodiment;

FIG. 9 is a flowchart illustrating a control method of the inspection apparatus according to the second embodiment;

FIG. 10 is a configuration diagram illustrating an inspection apparatus according to a first modified example of the second embodiment; and

FIG. 11 is a flowchart illustrating a control method of the inspection apparatus according to the first modified example of the second embodiment.

### DESCRIPTION OF EMBODIMENTS

Hereinafter, embodiments of the present disclosure will be described with reference to the drawings. The following description is intended as a description of preferred embodiments of the present disclosure and is not intended to limit the scope of the present disclosure to the following embodiments. In the following description, same reference signs denote substantially similar contents.

### First Embodiment

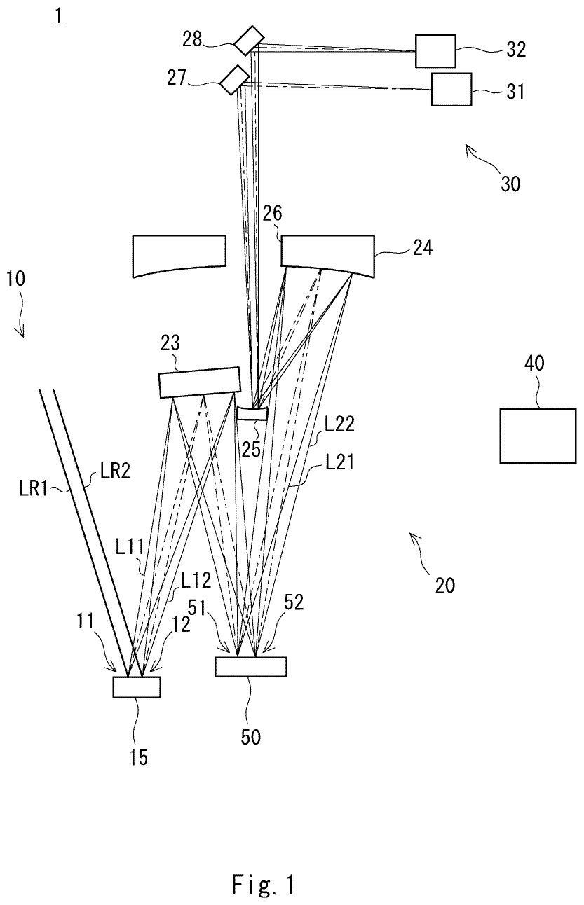

An optical apparatus according to a first embodiment will be described. Hereinafter, an inspection apparatus will be described as an example of an optical apparatus. Note that the optical apparatus is not limited to an inspection apparatus and may be other apparatuses such as a monitor apparatus and a manufacturing apparatus. FIG. 1 is a configuration diagram illustrating an inspection apparatus 1 according to the first embodiment. As shown in FIG. 1, the inspection apparatus 1 includes plasma forming means 10, an optical system 20, detecting means 30, and a control unit 40.

The plasma forming means 10 forms, as bright points, at least a first bright point 11 and a second bright point 12. The plasma forming means 10 forms bright points including the first bright point 11 and the second bright point 12 by generating plasma. Note that the number of bright points is not limited to two and may be three or more. For example, the plasma forming means 10 generates plasma to become the first bright point 11 and plasma to become the second bright point 12 by irradiating a target material 15 with a plurality of excitation light rays LR1 and LR2. For example, the excitation light rays LR1 and LR2 are generated by a laser generating apparatus. The plasma forming means 10 may include a light source configured to generate or form least a first bright point 11 and a second bright point 12.

For example, the target material 15 contains tin (Sn), lithium (Li), or xenon ice. Note that the target material 15 may contain materials other than tin or the like as long as the target material 15 can form plasma when irradiated with excitation light ray LR1 and the like. In addition, a method used by the plasma forming means 10 to form plasma is not limited to the method of irradiating the target material 15 with excitation light rays LR. The plasma forming means 10 may form plasma by discharging the target material 15 arranged between electrodes.

The first bright point 11 and the second bright point 12 formed by the plasma forming means 10 become bright points for generating illuminating light. First illuminating light L11 is generated from the first bright point 11. Second illuminating light L12 is generated from the second bright point 12. The first illuminating light L11 and the second illuminating light L12 include EUV (Extreme Ultra Violet) light that is created when plasma is generated.

The optical system 20 illuminates an object 50 with critical illumination with plasma as bright points. For example, the object 50 may include a mask or the like in lithography using EUV light. The optical system 20 includes a mirror 23, a concave mirror 24, a mirror 25, a mirror 27, and a mirror 28. Note that the optical system 20 may include optical members other than the above. The mirror 23 illuminates a first region 51 of the object 50 with first critical illumination by the first illuminating light L11 generated from the first bright point 11. In addition, the mirror 23 illuminates a second region 52 of the object 50 with second critical illumination by the second illuminating light L12 generated from the second bright point 12. The optical system 20 may interpose, between the first bright point 11 and the first region 51 of the object 50, a mirror other than the mirror 23 as long as the first region 51 can be illuminated with the first critical illumination by the first illuminating light L11 generated from the first bright point 11. In addition, the optical system 20 may interpose, between the second bright point 12 and the second region 52 of the object 50, a mirror other than the mirror 23 as long as the second region 52 can be illuminated with the second critical illumination by the second illuminating light L12 generated from the second bright point 12. The second region 52 of the object 50 is a region that differs from the first region 51. For example, the mirror 23 includes a concave mirror. Note that the mirror 23 is not limited to a concave mirror as long as the first region 51 can be illuminated with the first critical illumination and the second region 52 can be illuminated with the second critical illumination.

Note that the first region 51 of the object 50 and the second region 52 of the object 50 are different regions in the same object 50. The first region 51 and the second region 52 may be regions that do not overlap with each other. The first region 51 and the second region 52 may be alternating regions. The second region 52 may be set at a position separated from the first region 51 by an integer multiple of a size of the first region 51. For example, when a scan direction is considered an X-axis, the second region 52 may be provided at a location separated by an integer multiple of the size of the first region 51 in a Y-axis direction. When the scan direction is considered the X-axis, the second region 52 may be provided at a location separated by an integer multiple of the size of the first region 51 in the X-axis direction. Alternatively, when the scan direction is considered the X-axis, the second region 52 may be provided at a location separated by an integer multiple of the size of the first region 51 in a direction intersecting the X-axis direction and the Y-axis direction.

The optical system 20 illuminates the second region 52 of the object 50 with the second critical illumination when illuminating the first region 51 of the object 50 with the first critical illumination. In other words, the optical system 20 illuminates the second region 52 at a same timing as the optical system 20 illuminates the first region 51. Accordingly, a state of the first region 51 and a state of the second region 52 can be inspected at the same timing and in association with each other. Note that the optical system 20 may illuminate the second region 52 at a timing staggered with respect to the timing of illuminating the first region 51. Accordingly, for example, a degree of freedom of irradiation timings of the excitation light rays LR1 and LR2 can be increased.

In the inspection apparatus 1 according to the present embodiment, it is not necessary to provide an optical diaphragm on an optical path of the first illuminating light L11 and the second illuminating light L12 from bright points such as the first bright point 11 and the second bright point 12 to the object 50.

Secondary light is emitted from the object 50 illuminated by the first critical illumination. For example, the secondary light may include at least one of the following: reflected light of the first illuminating light L11 reflected by the object 50; scattered light of the first illuminating light L11 scattered by the object 50; diffracted light of the first illuminating light L11 diffracted by the object 50; and light emitted by the object 50 due to excitation of the first illuminating light L11. The secondary light from the object 50 illuminated by the first critical illumination will be referred to as first light L21. In a similar manner, secondary light from the object 50 illuminated by the second critical illumination will be referred to as second light L22.

The first light L21 and the second light L22 are incident on the concave mirror 24. The concave mirror 24 has a hole 26 in a central part thereof. The first light L21 and the second light L22 incident on the concave mirror 24 are reflected by the concave mirror 24 and are incident on the mirror 25. The first light L21 and the second light L22 incident on the mirror 25 are reflected by the mirror 25.

The first light L21 reflected by the mirror 25 passes through the hole 26 and is incident on the mirror 27. The first light L21 is reflected by the mirror 27 and is incident on first detecting means 31. On the other hand, the second light L22 reflected by the mirror 25 passes through the hole 26 and is incident on the mirror 28. The second light L22 is reflected by the mirror 28 and is incident on second detecting means 32.

The detecting means 30 detects secondary light from the object 50 illuminated by critical illumination of illuminating light. The detecting means 30 includes the first detecting means 31 and the second detecting means 32. The first detecting means 31 detects the first light L21 that includes secondary light from the object 50 illuminated by the first critical illumination. The second detecting means 32 detects the second light L22 that includes secondary light from the object 50 illuminated by the second critical illumination. For example, the detecting means 30 such as the first detecting means 31 and the second detecting means 32 may include an image capturing element such as a CCD (Charge Coupled Device) or a CMOS sensor.

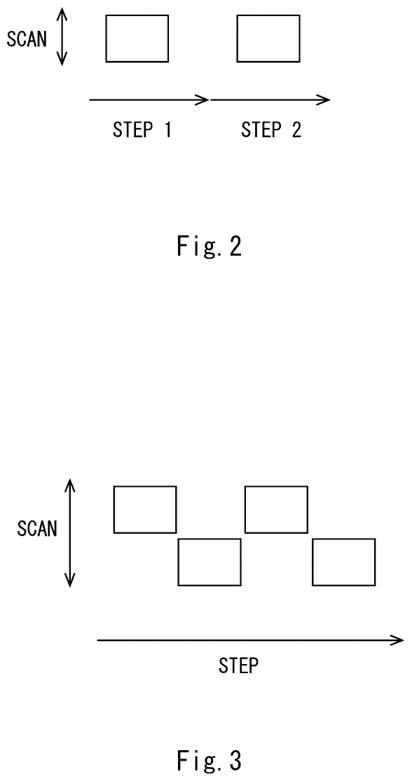

FIGS. 2 and 3 are diagrams illustrating an arrangement of the first detecting means 31 and the second detecting means 32 in the inspection apparatus 1 according to the first embodiment. As shown in FIG. 2, the first detecting means 31 and the second detecting means 32 may be arranged lined up in a direction orthogonal to a scan direction as viewed from an optical axis direction of the first light L21 and the second light L22. In addition, as shown in FIG. 3, the first detecting means 31 and the second detecting means 32 may be alternately provided in a staggered manner as viewed from the optical axis direction of the first light L21 and the second light L22. For example, the first detecting means 31 and the second detecting means 32 may be arranged lined up in the scan direction and in a direction intersecting the scan direction.

The inspection apparatus 1 may include the control unit 40. The control unit 40 is connected to each member of the inspection apparatus 1 such as the detecting means 30 and the laser generating apparatus in the plasma forming means 10 via a wireless or wired communication line in such a manner that allows information to be transmitted. The control unit 40 controls each member of the inspection apparatus 1. The control unit 40 may be an information processing apparatus such as a PC (Personal Computer), a server, or a microcomputer. Such an information processing apparatus may further include a processor, a memory, a storage apparatus, and a user interface. The storage apparatus stores, in the form of a program, processing to be executed by each component of the information processing apparatus. In addition, the processor causes the program to be loaded onto the memory from the storage apparatus and executes the program. Accordingly, the processor realizes functions of each component in the information processing apparatus. The user interface may include an input apparatus such as a keyboard or a mouse and an output apparatus such as a display, a printer, or a speaker.

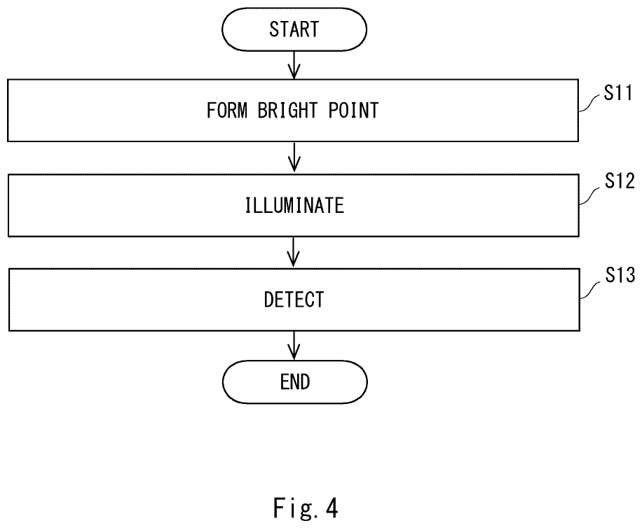

FIG. 4 is a flowchart illustrating a control method of the inspection apparatus 1 according to the first embodiment. As shown in FIG. 4, the control method includes a bright point formation step S11, an illumination step S12, and a detection step S13.

In the bright point formation step S11, the control unit 40 causes the plasma forming means 10 to form, as bright points, at least the first bright point 11 and the second bright point 12.

In the illumination step S12, the control unit 40 causes the optical system 20 to illuminate the first region 51 of the object 50 with first critical illumination by the first illuminating light L11 generated from the first bright point 11 and causes the optical system 20 to illuminate the second region 52 of the object 50 with second critical illumination by the second illuminating light L12 generated from the second bright point 12.

In the detection step S13, the control unit 40 causes the first detecting means 31 in the detecting means 30 to detect the first light L21 that includes secondary light from the object 50 illuminated by the first critical illumination. In addition, the control unit 40 causes the second detecting means 32 in the detecting means 30 to detect the second light L22 that includes secondary light from the object 50 illuminated by the second critical illumination. In this manner, the control unit 40 can inspect the object 50 by controlling the inspection apparatus 1.

Next, an advantageous effect of the inspection apparatus 1 according to the present embodiment will be described. The inspection apparatus 1 according to the present first embodiment forms a plurality of bright points including at least the first bright point 11 and the second bright point 12. In addition, two different regions (the first region 51 and the second region 52) of the object 50 are critically illuminated by the first illuminating light L11 and the second illuminating light L12 generated from the respective bright points. In this manner, throughput of inspection can be improved by subjecting different regions to critical illumination.

In a case of a system that performs inspections at high magnification, illumination intensity (irradiation density) to the object 50 must be increased. However, excessively increasing illumination intensity with respect to the object 50 that contains materials with heat input limitations results in degradation of the object 50. In the present embodiment, power of illuminating light is distributed to the first illuminating light L11 and the second illuminating light L12 by configuring an illumination region to the object 50 so as to include a plurality of regions. In addition, throughput can be improved by arranging the detecting means 30 so as to observe a position corresponding to the illumination region.

Although throughput can also be improved by making the detecting means 30 larger to process larger amounts of data, the physical size of the detecting means 30 becomes a problem. In such a case, a system using a plurality of detecting means including the first detecting means 31 and the second detecting means 32 as in the present embodiment is effective.

### Modified Example 1-1

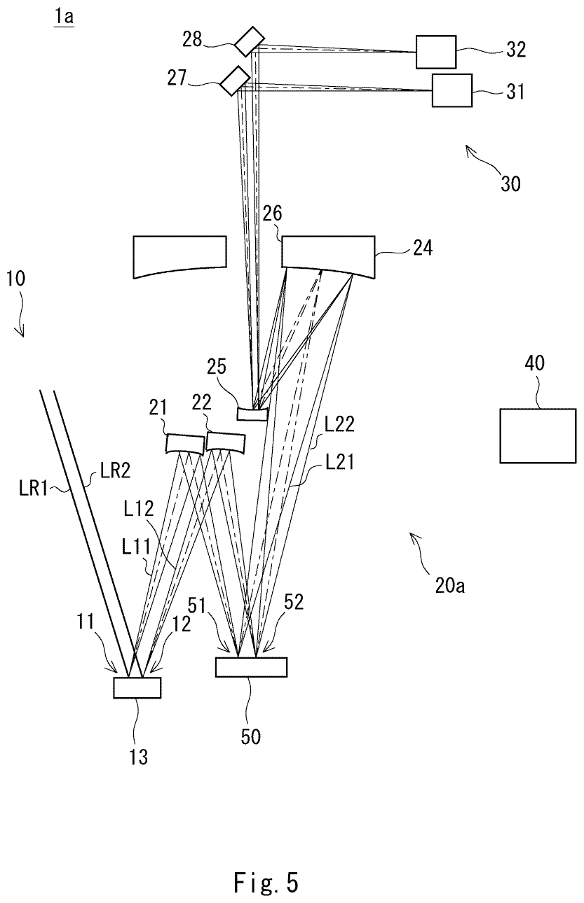

Next, a first modified example of the first embodiment will be described. FIG. 5 is a configuration diagram illustrating an inspection apparatus 1a according to the first modified example of the first embodiment. As shown in FIG. 5, in the inspection apparatus 1a, an optical system 20a includes a first elliptical mirror 21 and a second elliptical mirror 22 in place of the mirror 23.

The first elliptical mirror 21 illuminates the first region 51 of the object 50 with first critical illumination by the first illuminating light L11 generated from a first light flux of light from the first bright point 11. The optical system 20a may interpose, between the first bright point 11 and the first region 51 of the object 50, a mirror other than the first elliptical mirror 21 such as another elliptical mirror or a mirror of a different shape as long as the first region 51 can be illuminated with the first critical illumination by the first illuminating light L11 generated by any first light flux of light from the first bright point 11.

The second elliptical mirror 22 illuminates the second region 52 of the object 50 with second critical illumination by the second illuminating light L12 generated from a second light flux of light from the second bright point 12. The optical system 20a may interpose, between the second bright point 12 and the second region 52 of the object 50, a mirror other than the second elliptical mirror 22 such as another elliptical mirror or a mirror of a different shape as long as the second region 52 can be illuminated with the second critical illumination by the second illuminating light L12 generated by any second light flux of light from the second bright point 12 that differs from the first light flux. The first and second light fluxes may be exclusive or, in other words, none of the light fluxes in the first light flux need be included in the second light flux and none of the light fluxes in the second light flux need be included in the first light flux.

The first elliptical mirror 21 may have one focusing point at a position of the first bright point 11. In this case, a mirror may be interposed so as to make the one focusing point of the first elliptical mirror 21 the position of the first bright point 11. Such an example is also included in the first elliptical mirror 21 having one focusing point at the position of the first bright point 11. The first elliptical mirror 21 may have another focusing point at a position of the first region 51. In this case, a mirror may be interposed so as to make the other focusing point of the first elliptical mirror 21 the position of the first region 51. Such an example is also included in the first elliptical mirror 21 having the other focusing point at the position of the first region 51. The second elliptical mirror 22 may have one focusing point at a position of the second bright point 12. In this case, a mirror may be interposed so as to make the one focusing point of the second elliptical mirror 22 the position of the second bright point 12. Such an example is also included in the second elliptical mirror 22 having one focusing point at the position of the second bright point 12. The second elliptical mirror 22 may have another focusing point at a position of the second region 52. In this case, a mirror may be interposed so as to make the other focusing point of the second elliptical mirror 22 the position of the second region 52. Such an example is also included in the second elliptical mirror 22 having the other focusing point at the position of the second region 52. The first elliptical mirror 21 may have one focusing point at the position of the first bright point 11 or have another focusing point at the position of the first region 51. The first elliptical mirror 21 may have one focusing point at the position of the first bright point 11 and have another focusing point at the position of the first region 51. The second elliptical mirror 22 may have one focusing point at the position of the second bright point 12 or have another focusing point at the position of the second region 52. The second elliptical mirror 22 may have one focusing point at the position of the second bright point 12 and have another focusing point at the position of the second region 52. The first elliptical mirror 21 may have one focusing point at the position of the first bright point 11 and have another focusing point at the position of the first region 51 and, at the same time, the second elliptical mirror 22 may have one focusing point at the position of the second bright point 12 and have another focusing point at the position of the second region 52. A configuration such as any of the above enables a minimum number of optical members to be used and light loss of the first illuminating light L11 and the second illuminating light L12 due to the optical members to be reduced. Therefore, the optical system 20a illuminates the first region 51 of the object 50 with high brightness with first critical illumination by the first illuminating light L11 generated from the first bright point 11 and illuminates the second region 52 of the object 50 with high brightness with second critical illumination by the second illuminating light L12 generated from the second bright point 12.

Even in the optical system 20a, it is not necessary to provide an optical diaphragm on an optical path of the first illuminating light L11 and the second illuminating light L12 from the first bright point 11 and the second bright point 12 to the object 50.

According to the present embodiment, the inspection apparatus 1a includes the first elliptical mirror 21 and the second elliptical mirror 22. Since positioning of the optical system 20a need only involve respectively aligning the one focusing point of the first elliptical mirror 21 and the one focusing point of the second elliptical mirror 22 at the position of the first bright point 11 and at the position of the second bright point 12 and respectively aligning the other focusing points with the first region 51 and the second region 52, positioning can be readily performed. In addition, since the first region 51 and the second region 52 can be efficiently illuminated with the first illuminating light L11 and the second illuminating light L12 incident on the first elliptical mirror 21 and the second elliptical mirror 22, inspection accuracy can be improved.

### Modified Example 1-2

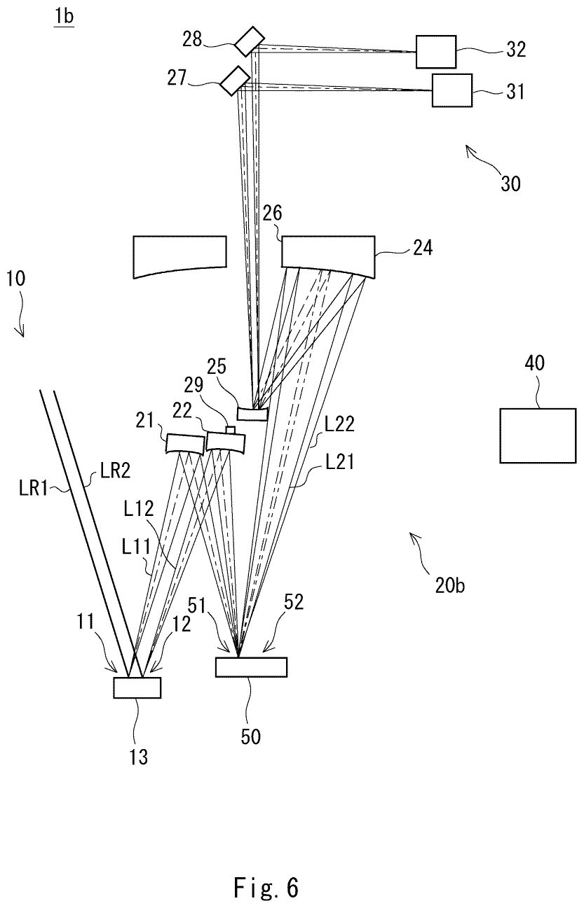

Next, a second modified example of the first embodiment will be described. FIG. 6 is a configuration diagram illustrating an inspection apparatus 1b according to the second modified example of the first embodiment. As shown in FIG. 6, in the inspection apparatus 1b, an optical system 20b further includes switching means 29. For example, the switching means 29 is mounted to the second elliptical mirror 22. The switching means 29 can change an orientation of a reflective surface of the second elliptical mirror 22. Accordingly, the second illuminating light L12 having been illuminating the second region 52 with the second critical illumination changes so as to illuminate the first region 51 with the second critical illumination. A mode in which the second region 52 is illuminated with the second critical illumination is referred to as a first mode. More specifically, the first mode is a mode in which the first region 51 is illuminated with the first critical illumination and the second region 52 is illuminated with the second critical illumination. A mode in which the first region 51 is illuminated with the second critical illumination is referred to as a second mode. More specifically, the second mode is a mode in which the first region 51 is illuminated with both the first critical illumination and the second critical illumination. Accordingly, the switching means 29 has a function of switching to the first mode or the second mode. The switching means 29 may include one or more actuators, controlled by the control unit 40, configured to change an orientation of a reflective surface of the second elliptical mirror 22.

Note that the optical system 20b may interpose, between the second bright point 12 and the first region 51 of the object 50, a mirror other than the second elliptical mirror 22 such as another elliptical mirror or a mirror of a different shape even when illuminating the first region 51 with the second critical illumination by the second illuminating light L12 generated from the second bright point 12.

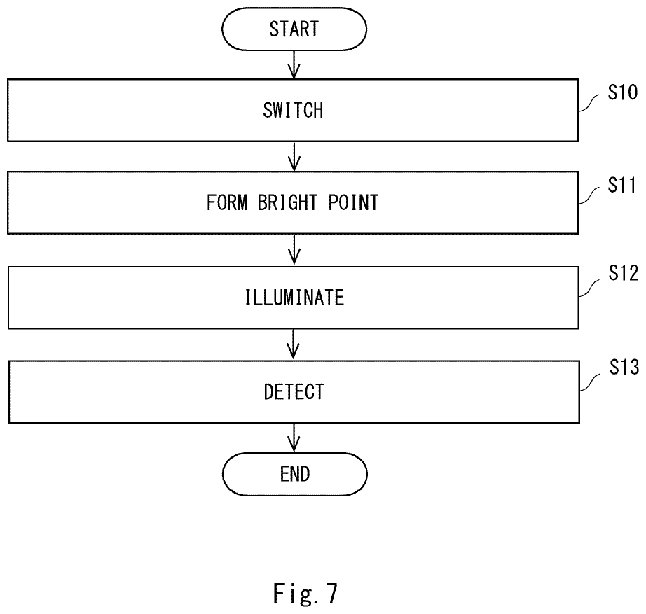

FIG. 7 is a flowchart illustrating a control method of the inspection apparatus 1b according to the second modified example of the first embodiment. As shown in FIG. 7, the control method of the inspection apparatus 1b according to the second modified example further includes a switching step S10. In the switching step S10, the control unit 40 causes the switching means 29 to switch to the first mode in which the second region 52 is illuminated by the second critical illumination or to the second mode in which the first region 51 is illuminated by the second critical illumination. Note that although the switching step S10 is performed before the bright point formation step S11 in FIG. 7, the switching step S10 is not limited thereto. The switching step S10 may be performed after any of the bright point formation step S11, the illumination step S12, and the detection step S13.

Since the inspection apparatus 1b according to the present modified example includes the switching means 29, the inspection apparatus 1b can switch to the first mode which improves throughput of inspections and to the second mode which increases brightness of the first region 51 and improves inspection accuracy. Therefore, inspection conditions can be diversified.

### Second Embodiment

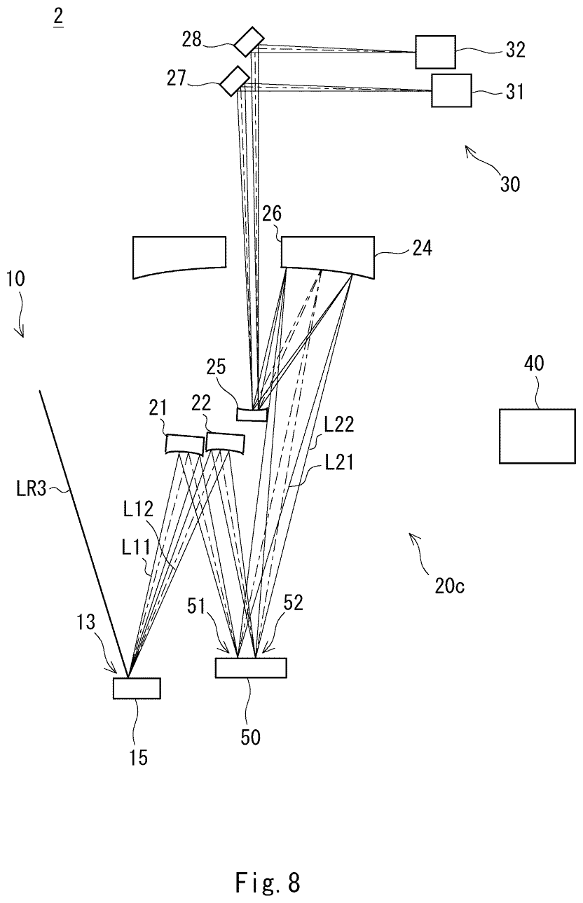

FIG. 8 is a configuration diagram illustrating an inspection apparatus 2 according to a second embodiment. As shown in FIG. 8, in the inspection apparatus 2 according to the present embodiment, an optical system 20c includes the first elliptical mirror 21 and the second elliptical mirror 22 in place of the mirror 23. In addition, the inspection apparatus 2 according to the present embodiment need not include the plasma forming means 10 which forms the first bright point 11 and the second bright point 12. In other words, in this embodiment, the plasma forming means 10 may include a light source configured to generate or form at least one bright point 13. For example, a bright point 13 may be formed by irradiating the target material 15 with excitation light ray LR3. Note that the bright point 13 is not limited to being formed by irradiation of the excitation light ray LR3 and may be formed by discharging the target material 15 arranged between electrodes.

The first elliptical mirror 21 illuminates the first region 51 of the object 50 with first critical illumination by the first illuminating light L11 generated from the bright point 13. The optical system 20c may interpose, from the bright point 13 to the first region 51 of the object 50, a mirror other than the first elliptical mirror 21 such as another elliptical mirror or a mirror of a different shape as long as the first region 51 can be illuminated with the first critical illumination by the first illuminating light L11 generated from the bright point 13.

The first elliptical mirror 21 may have one focusing point at a position of the bright point 13. Even in this case, the first elliptical mirror 21 illuminates the first region 51 of the object 50 with first critical illumination by the first illuminating light L11 generated from the bright point 13. Note that in doing so, a mirror may be interposed so as to make the one focusing point of the first elliptical mirror 21 the position of the bright point 13. Such an example is also included in the one focusing point of the first elliptical mirror 21 assuming the position of the bright point 13.

The second elliptical mirror 22 may have one focusing point at a position of the bright point 13. Even in this case, the second elliptical mirror 22 illuminates the second region 52 of the object 50 with second critical illumination by the second illuminating light L12 generated from the bright point 13. Note that in doing so, a mirror may be interposed so as to make the one focusing point of the second elliptical mirror 22 the position of the bright point 13. Such an example is also included in the one focusing point of the second elliptical mirror 22 assuming the position of the bright point 13.

The first elliptical mirror 21 may have another focusing point at a position of the first region 51. The second elliptical mirror 22 may have another focusing point at a position of the second region 52. Accordingly, the amount of light illuminating the object 50 can be increased. Note that in doing so, a mirror may be interposed so as to make the other focusing point of the first elliptical mirror 21 the position of the first region 51 or a mirror may be interposed so as to make the other focusing point of the second elliptical mirror 22 the position of the second region 52. Such an example is also included in the other focusing point of the first elliptical mirror 21 assuming the position of the first region 51 and the other focusing point of the second elliptical mirror 22 assuming the position of the second region 52.

In the present embodiment, it is not necessary to provide an optical diaphragm on an optical path of the first illuminating light L11 and the second illuminating light L12 from the bright point 13 to the object 50.

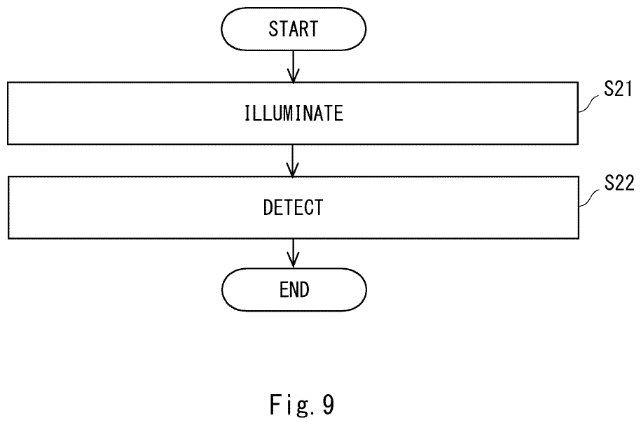

FIG. 9 is a flowchart illustrating a control method of the inspection apparatus 2 according to the second embodiment. As shown in FIG. 9, the control method of the inspection apparatus 2 according to the second embodiment includes an illumination step S21 and a detection step S22. In the illumination step S21, the control unit 40 may cause the first elliptical mirror 21 having one focusing point at a position of the bright point 13 in the optical system 20c to illuminate the first region 51 of the object 50 with first critical illumination by the first illuminating light L11 generated from the bright point 13. At the same time, the control unit 40 may cause the second elliptical mirror 22 having one focusing point at a position of the bright point 13 in the optical system 20c to illuminate the second region 52 of the object 50 with second critical illumination by the second illuminating light L12 generated from the bright point 13. The detection step S22 is similar to the detection step S13.

The inspection apparatus 2 according to the present embodiment includes the bright point 13. Positioning of the optical system 20c may be facilitated by aligning the one focusing point of the first elliptical mirror 21 and the one focusing point of the second elliptical mirror 22 at the position of the bright point 13. In addition, since the first region 51 and the second region 52 can be efficiently illuminated with the first illuminating light L11 and the second illuminating light L12 incident on the first elliptical mirror 21 and the second elliptical mirror 22, inspection accuracy can be improved.

### Modified Example 2-1

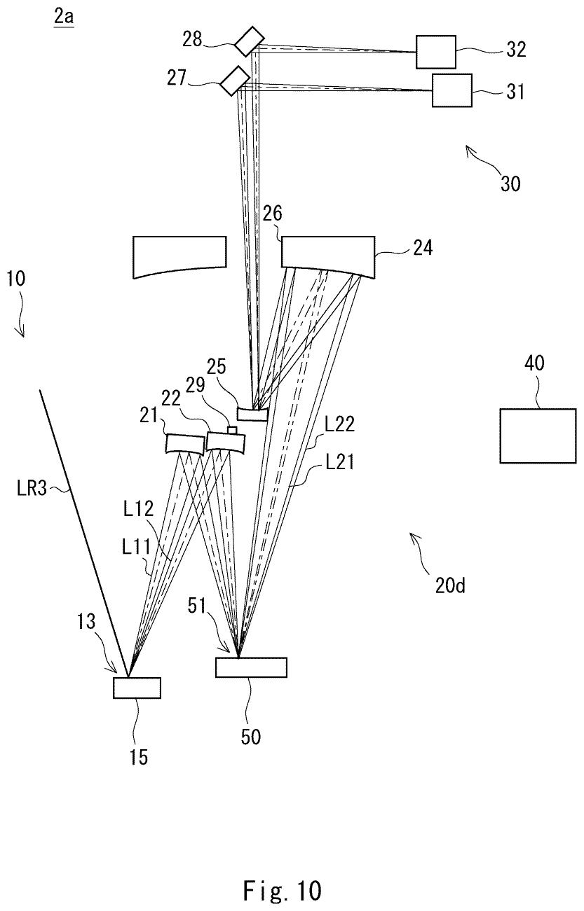

Next, a first modified example of the second embodiment will be described. FIG. 10 is a configuration diagram illustrating an inspection apparatus 2a according to the first modified example of the second embodiment. As shown in FIG. 10, in the inspection apparatus 2a, an optical system 20d further includes the switching means 29. For example, the switching means 29 changes an orientation of a reflective surface of the second elliptical mirror 22. Accordingly, the second illuminating light L12 having been illuminating the second region 52 with the second critical illumination changes so as to illuminate the first region 51 with the second critical illumination. In a similar manner to the second modified example of the first embodiment described earlier, a mode in which the second region 52 is illuminated with the second critical illumination is referred to as a first mode and a mode in which the first region 51 is illuminated with the second critical illumination is referred to as a second mode. More specifically, the first mode is a mode in which the first region 51 is illuminated with the first critical illumination and the second region 52 is illuminated with the second critical illumination and the second mode is a mode in which the first region 51 is illuminated with both the first critical illumination and the second critical illumination. Therefore, the switching means 29 has a function of switching to the first mode or the second mode.

Note that the optical system 20d may interpose, between the bright point 13 and the first region 51 of the object 50, a mirror other than the second elliptical mirror 22 such as another elliptical mirror or a mirror of a different shape even when illuminating the first region 51 with the second critical illumination by the second illuminating light L12 generated from the bright point 13.

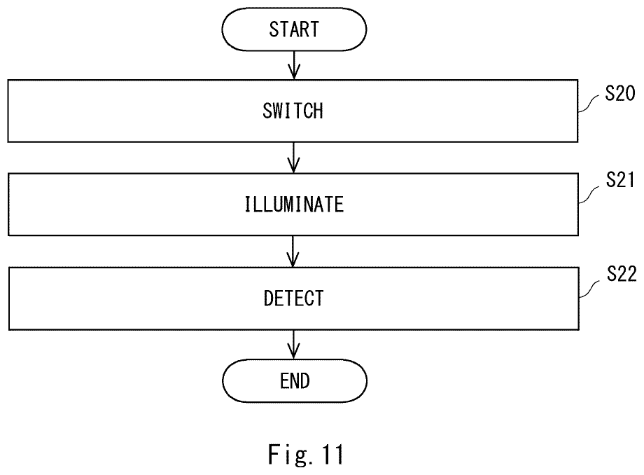

FIG. 11 is a flowchart illustrating a control method of the inspection apparatus 2a according to the first modified example of the second embodiment. As shown in FIG. 11, the control method of the inspection apparatus 2a further includes a switching step S20. In the switching step S20, the control unit 40 causes the switching means 29 to switch to the first mode in which the second region 52 is illuminated by the second critical illumination or to the second mode in which the first region 51 is illuminated by the second critical illumination. Note that although the switching step S20 is performed before the illumination step S21 in FIG. 11, the switching step S20 is not limited thereto. The switching step S20 may be performed after any of the illumination step S21 and the detection step S22.

Since the inspection apparatus 2a according to the present modified example includes the switching means 29, the inspection apparatus 2a can switch to the first mode which improves throughput of inspections and to the second mode which increases brightness of the first region 51 and improves inspection accuracy. Therefore, inspection conditions can be diversified.

While embodiments of the present disclosure have been described above, the present disclosure includes appropriate modifications that do not impair its purpose and advantages and, further, the present disclosure is not limited by the above embodiments. The one or more mirrors or one or more elliptical mirrors described in each embodiment may be replaced with one or more facet mirrors. The facet mirror includes a mirror having multiple mirror elements that can be individually adjusted in position. In addition, configurations that appropriately omit and combine respective components of the first and second embodiments and the respective modified examples are also within the scope of the technical concepts of the present disclosure.

The first and second embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An optical apparatus, comprising:
an optical system configured to illuminate an object with critical illumination with plasma as a bright point;
detecting unit configured to detect secondary light from the object illuminated by the critical illumination; and
plasma forming unit configured to form at least a first bright point and a second bright point as the bright point, wherein
the optical system is configured to:
illuminate a first region of the object with first critical illumination by first illuminating light generated from the first bright point; and
illuminate a second region of the object that differs from the first region of the object with second critical illumination by second illuminating light generated from the second bright point, and
the detecting unit includes:
first detecting unit configured to detect first light including the secondary light from the object illuminated by the first critical illumination; and
second detecting unit configured to detect second light including the secondary light from the object illuminated by the second critical illumination.

2. An optical apparatus, comprising:
an optical system configured to illuminates an object with critical illumination with plasma as a bright point; and
detecting unit configured to detect secondary light from the object illuminated by the critical illumination, wherein
the optical system includes:
a first elliptical mirror configured to illuminate a first region of the object with first critical illumination by first illuminating light generated from a first light flux of light from the bright point; and
a second elliptical mirror configured to illuminate a second region of the object that differs from the first region of the object with second critical illumination by second illuminating light generated from a second light flux of the light from the bright point that differs from the first light flux of the light from the bright point, and
the detecting unit includes:
first detecting unit configured to detect first light including the secondary light from the object illuminated by the first critical illumination; and
second detecting unit configured to detect second light including the secondary light from the object illuminated by the second critical illumination.

3. The optical apparatus according to claim 1, wherein
the optical system is configured to illuminate the second region of the object with the second critical illumination when illuminating the first region of the object with the first critical illumination.

4. The optical apparatus according to claim 1, wherein
the optical system includes switching unit configured to switch to a first mode in which the second region is illuminated by the second critical illumination or a second mode in which the first region is illuminated by the second critical illumination.

5. The optical apparatus according to claim 1, wherein
the first detecting unit and the second detecting unit are alternately provided in a staggered manner as viewed from an optical axis direction of the first light and the second light.

6. The optical apparatus according to claim 1, wherein
the optical system includes:
a first elliptical mirror including one focusing point at a position of the first bright point and another focusing point at a position of the first region; and
a second elliptical mirror including one focusing point at a position of the second bright point and another focusing point at a position of the second region.

7. The optical apparatus according to claim 2, wherein
the first elliptical mirror includes one focusing point at a position of the bright point and another focusing point at a position of the first region, and
the second elliptical mirror includes one focusing point at a position of the bright point and another focusing point at a position of the second region.

8. The optical apparatus according to claim 6, wherein
a diaphragm is not provided on an optical path of the first illuminating light and the second illuminating light from the bright point to the object.

9. A control method of an optical apparatus including:
an optical system configured to illuminate an object with critical illumination with plasma as a bright point;
detecting unit configured to detect secondary light from the object illuminated by the critical illumination; and
plasma forming unit configured to form at least a first bright point and a second bright point as the bright point,
the control method of the optical apparatus comprising:
a bright point forming step of causing the plasma forming unit to form at least the first bright point and the second bright point as the bright point;
an illuminating step of causing the optical system to illuminate a first region of the object with first critical illumination by first illuminating light generated from the first bright point and to illuminate a second region of the object that differs from the first region of the object with second critical illumination by second illuminating light generated from the second bright point; and
a detecting step of causing first detecting unit in the detecting unit to detect first light including the secondary light from the object illuminated by the first critical illumination and causing second detecting unit in the detecting unit to detect second light including the secondary light from the object illuminated by the second critical illumination.

10. A control method of an optical apparatus including:
an optical system configured to illuminate an object with critical illumination with plasma as a bright point; and
detecting unit configured to detect secondary light from the object illuminated by the critical illumination,
the control method of the optical apparatus comprising:
an illuminating step of causing a first elliptical mirror in the optical system to illuminate a first region of the object with first critical illumination by first illuminating light generated from a first light flux of light from the bright point and causing a second elliptical mirror in the optical system to illuminate a second region of the object that differs from the first region of the object with second critical illumination by second illuminating light generated from a second light flux of the light from the bright point that differs from the first light flux of the light from the bright point; and
a detecting step of causing first detecting unit in the detecting unit to detect first light including the secondary light from the object illuminated by the first critical illumination and causing second detecting unit in the detecting unit to detect second light including the secondary light from the object illuminated by the second critical illumination.

11. The control method of the optical apparatus according to claim 9, wherein
in the illuminating step,
the optical system is caused to illuminate the second region of the object with the second critical illumination when illuminating the first region of the object with the first critical illumination.

12. The control method of the optical apparatus according to claim 9, further comprising:
a switching step of causing switching unit to switch to a first mode in which the second region is illuminated by the second critical illumination or to a second mode in which the first region is illuminated by the second critical illumination.

13. The control method of the optical apparatus according to claim 9, wherein
the first detecting unit and the second detecting unit are alternately provided in a staggered manner as viewed from an optical axis direction of the first light and the second light.

14. The control method of the optical apparatus according to claim 9, wherein
in the illuminating step,
the first region is illuminated by a first elliptical mirror including one focusing point at a position of the first bright point and another focusing point at a position of the first region, and
the second region is illuminated by a second elliptical mirror including one focusing point at a position of the second bright point and another focusing point at a position of the second region.

15. The control method of the optical apparatus according to claim 10, wherein
in the illuminating step
the first elliptical mirror includes one focusing point at a position of the bright point and another focusing point at a position of the first region, and
the second elliptical mirror includes one focusing point at a position of the bright point and another focusing point at a position of the second region.

16. The control method of the optical apparatus according to claim 14, wherein
in the illuminating step,
a diaphragm is not provided on an optical path of the first illuminating light and the second illuminating light from the bright point to the object.
